(19) United States
(12) Patent Application Publication
(10) Pub. No.: US 2025/0294785 A1
(43) Pub. Date: Sep. 18, 2025

(54) SEMICONDUCTOR PROCESSING FOR BIPOLAR JUNCTION TRANSISTOR (BJT)

(71) Applicant: TEXAS INSTRUMENTS INCORPORATED, Dallas, TX (US)

(72) Inventors: Robert Cassel, Lehi, UT (US); Gordon Nielsen, Cedar Hills, UT (US); Jonathan Lane, Sandy, UT (US); Christopher Thompson, Salt Lake City, UT (US)

(21) Appl. No.: 18/608,669

(22) Filed: Mar. 18, 2024

(51) Int. Cl. H01L 29/737; H01L 29/08; H01L 29/66

(52) U.S. Cl. CPC H10D 10/821; H10D 10/021; H10D 62/136

(57) ABSTRACT

The present disclosure generally relates to semiconductor processing for a bipolar junction transistor (BJT). In an example, a semiconductor device includes a semiconductor substrate and a bipolar junction transistor on the semiconductor substrate. The bipolar junction transistor includes a collector layer on the semiconductor substrate, a base layer on the collector layer, a raised base layer on the base layer, a dielectric spacer on the base layer and along a sidewall of the raised base layer, and an emitter layer on the base layer. The dielectric spacer is laterally between the raised base layer and the emitter layer. The emitter layer extends over the dielectric spacer and at least partially over the raised base layer. The raised base layer has a substantially continuous upper surface from a distance away from the emitter layer to the dielectric spacer underlying the emitter layer.

### BACKGROUND

Integrated circuits may include bipolar junction transistors (BJTs). BJTs may be desirable for their high gain characteristics to satisfy high performance and high current drive needs. Scaling of devices in an integrated circuit to smaller nodes typically requires novel approaches to semiconductor processing for fabricating those devices. Further, integrating a BJT with other devices may complicate that semiconductor processing.

### SUMMARY

An example described herein is a semiconductor device. The semiconductor device includes a semiconductor substrate and a bipolar junction transistor on the semiconductor substrate. The bipolar junction transistor includes a collector layer on the semiconductor substrate, a base layer on the collector layer, a raised base layer on the base layer, a dielectric spacer on the base layer and along a sidewall of the raised base layer, and an emitter layer on the base layer. The dielectric spacer is laterally between the raised base layer and the emitter layer. The emitter layer extends over the dielectric spacer and at least partially over the raised base layer. The raised base layer has a substantially continuous upper surface from a distance away from the emitter layer to the dielectric spacer underlying the emitter layer.

Another example is a method. A collector layer is formed on a semiconductor substrate. A base layer is formed on and contacting the collector layer. A raised base layer is formed on and contacting the base layer. After forming the raised base layer, an emitter layer is formed on and contacting the base layer and extending over the raised base layer.

A further example is a method. A bipolar junction transistor is formed including: epitaxially growing a base layer, forming an inverse mask over the base layer, epitaxially growing a raised base layer on the base layer while the inverse mask is over the base layer, and epitaxially growing an emitter layer on the base layer and laterally disposed from a sidewall of the raised base layer. The base layer is at least partially on a collector layer, and the collector layer is on a semiconductor substrate. The inverse mask defines the sidewall of the raised base layer. The emitter layer extends over the sidewall of the raised base layer.

The foregoing summary outlines rather broadly various features of examples of the present disclosure in order that the following detailed description may be better understood. Various features and advantages of such examples will be described hereinafter. The described examples may be readily utilized as a basis for modifying or designing other examples that are within the scope of the appended claims.

### BRIEF DESCRIPTION OF THE DRAWINGS

So that the manner in which the above recited features can be understood in detail, reference is made to the following detailed description taken in conjunction with the accompanying drawings.

FIGS. 1 through 26 are respective cross-sectional views of a semiconductor device in intermediate stages of manufacturing according to some examples.

FIG. 27 is a layout view of the bipolar junction transistor (BJT) of the semiconductor device of FIG. 26 according to some examples.

The drawings, and accompanying detailed description, are provided for understanding of features of various examples and do not limit the scope of the appended claims. The examples illustrated in the drawings and described in the accompanying detailed description may be readily utilized as a basis for modifying or designing other examples that are within the scope of the appended claims. Identical reference numerals may be used, where possible, to designate identical elements that are common among drawings. The figures are drawn to clearly illustrate the relevant elements or features and are not necessarily drawn to scale.

### DETAILED DESCRIPTION

Various features are described hereinafter with reference to the figures. Other examples may include any permutation of including or excluding aspects or features that are described. An illustrated example may not have all the aspects or advantages shown. An aspect or an advantage described in conjunction with a particular example is not necessarily limited to that example and can be practiced in any other examples even if not so illustrated or if not so explicitly described. Further, methods described herein may be described in a particular order of operations, but other methods according to other examples may be implemented in various other orders (e.g., including different serial or parallel performance of various operations) with more or fewer operations.

The present disclosure relates generally, but not exclusively, to semiconductor processing for a bipolar junction transistor (BJT). Some examples include a semiconductor device including a BJT. A BJT is on a semiconductor substrate. The BJT includes a collector layer, a base layer, a raised base layer, a dielectric spacer, and an emitter layer. The collector layer is on the semiconductor substrate. The base layer is on the collector layer, and the raised base layer is on the base layer. The dielectric spacer is on the base layer and along a sidewall of the raised base layer. The emitter layer is on the base layer. The dielectric spacer is laterally between the raised base layer and the emitter layer. The emitter layer extends over the dielectric spacer and at least partially over the raised base layer. The raised base layer has a substantially continuous upper surface from a distance away from the emitter layer to the dielectric spacer underlying the emitter layer. The raised base layer may be formed before the emitter layer. An inverse mask may be formed on the base layer, and the raised base layer may be formed while the inverse mask is on the base layer. The inverse mask may be removed, and the emitter layer may thereafter be formed. Semiconductor processing to form such a BJT may enable vertical and horizontal scaling of the BJT, which may improve characteristics of the BJT. Additionally, fewer processing steps may be implemented to achieve such BJT, which may simplify processing and reduce costs to manufacture. Other benefits and advantages may be achieved.

Various examples are described subsequently. Although the specific examples may illustrate various aspects of the above generally described features, examples may incorporate any combination of the above generally described features (which are described in more detail in examples below).

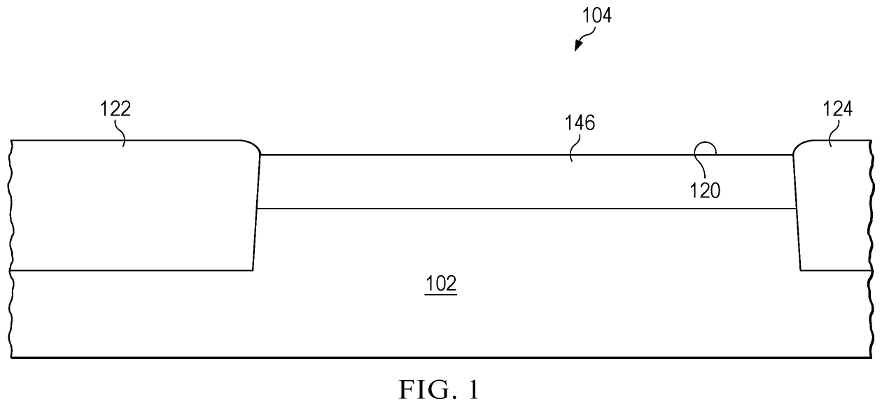

FIGS. 1 through 26 are respective cross-sectional views of a semiconductor device in intermediate stages of manufacturing according to some examples. Referring to FIG. 1, a semiconductor substrate 102 is provided. The semiconductor substrate 102 includes a BJT region 104 in which a BJT is to be formed. The semiconductor substrate may further include a p-type field effect transistor (pFET) region and an n-type field effect transistor (nFET) region. Together, the pFET region and the nFET region are included in a complementary field effect transistor (CFET) region. A pFET may be formed in the pFET region, and an nFET may be formed in the nFET region. Transition regions may be between the BJT region 104 and the CFET region (e.g., the pFET region and/or nFET region). Although aspects of the pFET region and nFET region are not illustrated in figures, processing for the pFET and nFET regions are described below. Processing for the pFET and nFET regions and illustrations in figures are in U.S. patent application Ser. No. 18/520,527, entitled “SEMICONDUCTOR PROCESSING INTEGRATION FOR BIPOLAR JUNCTION TRANSISTOR (BJT)”, filed on Nov. 27, 2023, the entirety of which is incorporated herein by reference.

The semiconductor substrate 102 may be or include a bulk semiconductor substrate, a semiconductor-on-insulator (SOI) substrate, or any other appropriate substrate. The semiconductor substrate 102 may also include a support (or handle) substrate and an epitaxial layer epitaxially grown on the support substrate. In some examples, the semiconductor substrate 102 is or includes a silicon substrate (which may be singulated from a bulk silicon wafer at the conclusion of semiconductor processing). In further examples, the semiconductor substrate 102 includes a silicon substrate with an epitaxial silicon layer grown thereon. The semiconductor substrate 102 is or includes a semiconductor material in and/or on which devices, such as the BJT, pFET, and nFET (as described subsequently), are formed. In some examples, the semiconductor material is or includes silicon (Si), silicon germanium (SiGe), gallium arsenide (GaAs), gallium nitride (GaN), the like, or a combination thereof. The semiconductor substrate 102 has an upper surface 120 in and/or on which devices (e.g., the BJT, pFET, and nFET) are formed. In the illustrated example, the semiconductor material of the semiconductor substrate 102 is p-doped with a p-type dopant. In some examples, the semiconductor substrate 102 is p-doped with a p-type dopant (e.g., boron (B)) with a concentration in a range from 1×10¹⁴ cm⁻³ to 1×10¹⁵ cm⁻³. Another dopant type and/or other doping concentrations may be implemented.

Isolation structures 122, 124 are formed on the semiconductor substrate 102. In the illustrated example, the isolation structures 122, 124, are shallow trench isolation structures (STIs) extending from the upper surface 120 of the semiconductor substrate 102 into the semiconductor substrate 102. As illustrated, the isolation structures 122, 124 are also raised above the upper surface 120 of the semiconductor substrate 102, and in other examples, the isolation structures 122, 124 may have respective upper surfaces co-planar with and/or below the upper surface 120 of the semiconductor substrate 102. The isolation structures 122, 124 may include, for example, a liner layer, such as including silicon oxide or silicon nitride, conformally along surfaces of a respective trench in the semiconductor substrate 102 and a fill isolation material, such as silicon oxide, over and on the liner layer.

The isolation structures 122, 124, as illustrated, may be formed by depositing a hardmask layer over the semiconductor substrate 102. The hardmask layer may be any appropriate material, such as silicon nitride, silicon oxynitride, or the like, and may be deposited using any appropriate deposition process, such as chemical vapor deposition (CVD). The hardmask layer is patterned, such as by using photolithography and an etching process (e.g., reactive ion etch (RIE)). Recesses or trenches are etched, such as by RIE, in the semiconductor substrate 102 using the patterned hardmask layer as a mask. The liner layer may then be conformally deposited in the recesses or trenches and over the patterned hardmask layer (or formed on exposed surfaces of the recesses or trenches—e.g., by an oxidation process), such as by plasma enhanced CVD (PECVD), and the fill isolation material may be deposited over the liner layer, such as by high aspect ratio CVD (HAR-CVD), flowable CVD (FCVD), or the like. Excess fill isolation material and liner layer may be removed from over the hardmask layer by a planarization process, such as a chemical mechanical polish (CMP). The hardmask layer may then be removed by an etch selective to the hardmask layer, which may be a wet etch process. In other examples, the isolation structures 122, 124 may be field oxide structures, such as local oxidation of silicon (LOCOS) structures, at the upper surface 120 of the semiconductor substrate 102, which may be formed using a LOCOS process.

The isolation structures 122, 124 laterally defines an active area of the upper surface 120 of the semiconductor substrate 102 on which the BJT is to be formed. The isolation structures 122, 124 together laterally encircle the active area of the upper surface 120 of the semiconductor substrate 102 on which the BJT is to be formed. As indicated subsequently, an active portion (e.g., a base layer) of the BJT extends laterally beyond the active area of the upper surface 120 of the semiconductor substrate 102 on which the BJT is formed and over the isolation structure 122.

An n-type doped sub-collector diffusion region 146 is formed in the semiconductor substrate 102. The n-type doped sub-collector diffusion region 146 may be formed by masking (e.g., by a photoresist using photolithography) areas of the semiconductor substrate 102 where an n-type doped sub-collector diffusion region is not to be formed and implanting n-type dopants into the semiconductor substrate 102. The n-type doped sub-collector diffusion region 146 extends from the upper surface 120 of the semiconductor substrate 102 into a depth in the semiconductor substrate 102 and is in the BJT region 104 laterally between the isolation structures 122, 124. A concentration of the n-type doped sub-collector diffusion region 146 is greater than a concentration of the p-type dopant of the p-type doped semiconductor substrate 102. In some examples, the n-type doped sub-collector diffusion region 146 is doped with an n-type dopant (e.g., phosphorus (P) or arsenic (As)) with a concentration in a range from 1×10¹⁸ cm⁻³ to 1×10²⁰ cm⁻³. Another dopant type and/or other doping concentrations may be implemented.

An n-type doped well may be formed in the semiconductor substrate 102 in the pFET region. The n-type doped well may be formed by masking (e.g., by a photoresist using photolithography) areas of the semiconductor substrate 102 where an n-type doped well is not to be formed and implanting n-type dopants into the semiconductor substrate 102. A concentration of the n-type dopant of the n-type doped well is greater than a concentration of the p-type dopant of the p-type doped semiconductor substrate 102. In some examples, the n-type doped well is doped with an n-type dopant with a concentration in a range from 1×10¹⁵ cm⁻³ to 1×10¹⁷ cm⁻³. Another dopant type and/or other doping concentrations may be implemented.

P-type doped wells may be formed in the semiconductor substrate 102. The p-type doped wells may be formed by masking (e.g., by a photoresist using photolithography) areas of the semiconductor substrate 102 where a p-type doped well is not to be formed and implanting p-type dopants into the semiconductor substrate 102. A p-type doped well may extend from the upper surface 120 of the semiconductor substrate 102 into a depth in the semiconductor substrate 102 and may be, e.g., in the BJT region 104 laterally exterior to the isolation structures 122, 124. This p-type doped well may be an isolation ring encircling the active area in which the BJT is to be formed. Another p-type doped well may be formed in the semiconductor substrate 102 in the nFET region. A concentration of the p-type dopant of the p-type doped wells may be greater than a concentration of the p-type dopant of the p-type doped semiconductor substrate 102. In some examples, the p-type doped wells may be doped with a p-type dopant (e.g., boron (B)) with a concentration in a range from 1×10¹⁵ cm⁻³ to 1×10¹⁷ cm⁻³. Another dopant type and/or other doping concentrations may be implemented.

Although the semiconductor substrate 102, n-type doped well(s), n-type doped sub-collector diffusion region 146, and p-type doped well(s) are described herein as being doped with a certain dopant conductivity type, such components may be doped with an opposite conductivity type (e.g., being n-type doped instead of p-type doped, and vice versa) in other examples. Similarly, subsequently described components that are described as being doped with a certain dopant conductivity type may also be doped with an opposite conductivity type in other examples.

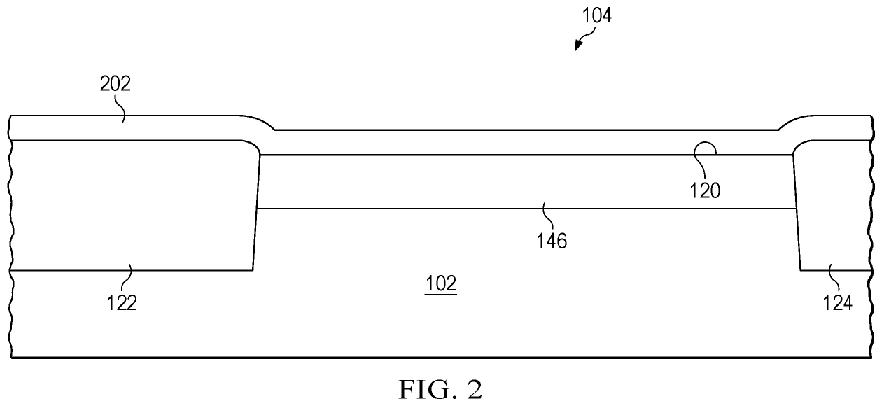

Referring to FIG. 2, a pedestal dielectric layer 202 is formed over the semiconductor substrate 102. The pedestal dielectric layer 202 is conformally deposited over the upper surface 120 of the semiconductor substrate 102 and the isolation structures 122, 124. In some examples, the pedestal dielectric layer 202 is silicon oxide (e.g., a tetraethyl orthosilicate (TEOS) oxide) deposited by CVD, although other dielectric materials and/or other deposition processes may be used in other examples.

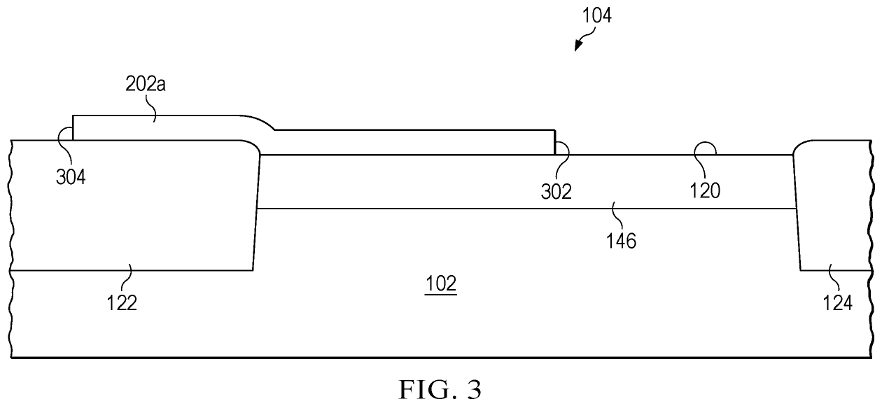

Referring to FIG. 3, the pedestal dielectric layer 202 is etched resulting in the pedestal dielectric layer 202a being in the BJT region 104. The pedestal dielectric layer 202 may be etched using appropriate photolithography and etching processes. For example, an anisotropic etch, such as an RIE, may be implemented. The pedestal dielectric layer 202a is over the upper surface 120 of the semiconductor substrate 102 in the BJT region 104 and extends laterally such that a sidewall 302 of the pedestal dielectric layer 202a is positioned over the upper surface 120 of the semiconductor substrate 102 in the BJT region 104. The pedestal dielectric layer 202a is over the isolation structure 122 in the BJT region 104 and extends laterally such that a sidewall 304 of the pedestal dielectric layer 202a is positioned over the isolation structure 122 in the BJT region 104.

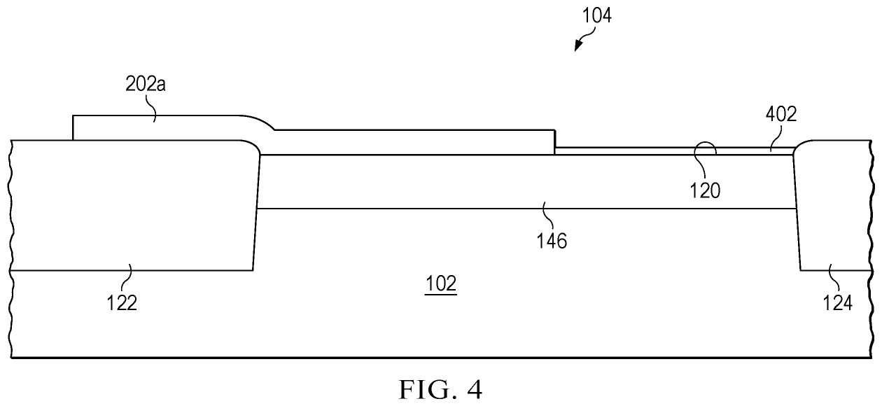

Referring to FIG. 4, a gate dielectric layer 402 is formed over the upper surface of the semiconductor substrate 102. In the illustrated example, the gate dielectric layer 402 is formed on exposed portions of the upper surface 120 of the semiconductor substrate 102 in the BJT region 104, which may further cause the gate dielectric layer 402 to be formed in the pFET region and nFET region. In the illustrated example, the gate dielectric layer 402 may be formed by an oxidation process, such as in situ steam generation (ISSG), which oxidizes the exposed portions of the upper surface 120 of the semiconductor substrate 102 to form an oxide as the gate dielectric layer 402. In other examples, other dielectric materials may be formed using an appropriate deposition process, which may conformally deposit the gate dielectric layer over the semiconductor substrate 102.

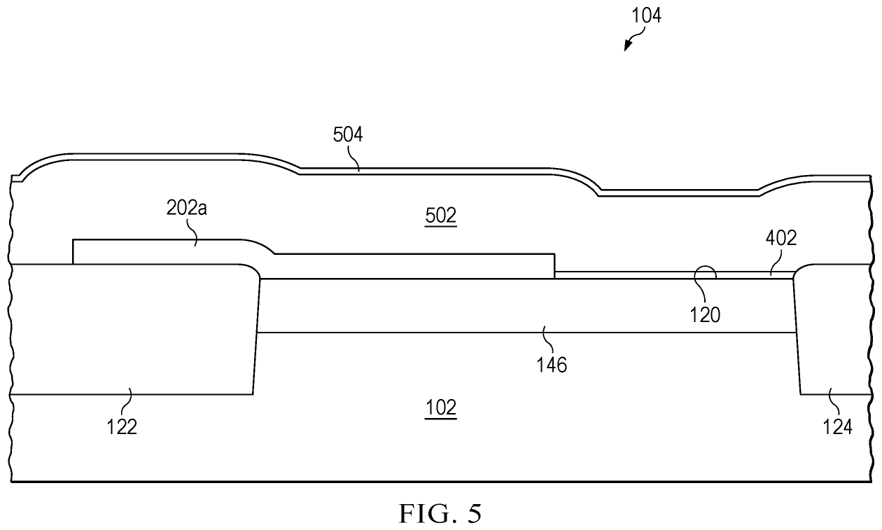

Referring to FIG. 5, a gate layer 502 is formed over the semiconductor substrate 102, and a dielectric protective layer 504 is formed over the gate layer 502. The gate layer 502 is formed over the gate dielectric layer 402, the isolation structures 122, 124, and the pedestal dielectric layer 202a. In some examples, the gate layer 502 is or includes a semiconductor material, such as polycrystalline silicon (polysilicon), and may be formed by any deposition process, such as CVD. In some examples, the semiconductor material may be doped in situ during deposition and/or may be implanted by a dopant after deposition. In some examples, the gate layer 502 is polysilicon doped with a p-type dopant with a concentration in a range from 1×10¹⁹ cm⁻³ to 1×10²¹ cm⁻³ after deposition and/or implantation. Other materials (e.g., conductive material) may be implemented as the gate layer 502, which may be formed by any deposition process. In some examples, the dielectric protective layer 504 is silicon oxide (e.g., a TEOS oxide) deposited by CVD, although other dielectric materials and/or other deposition processes may be used in other examples.

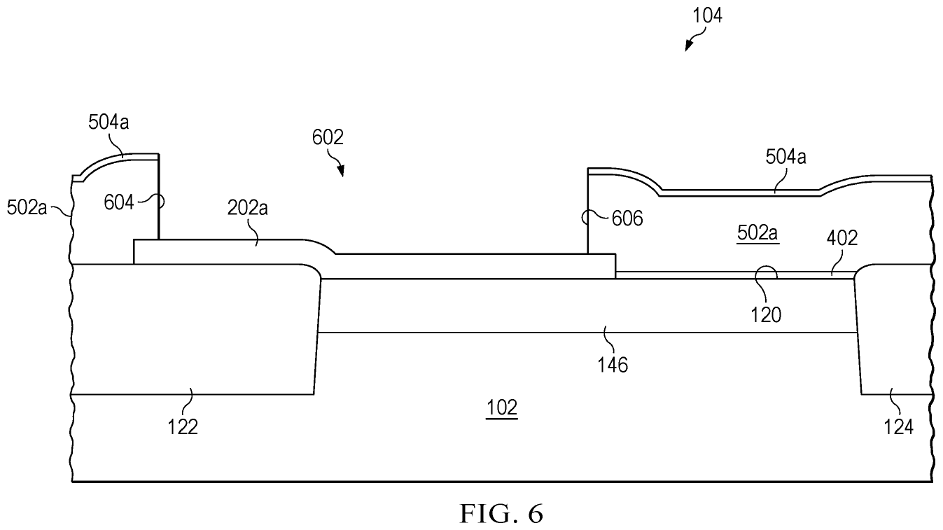

Referring to FIG. 6, the dielectric protective layer 504 and gate layer 502 are etched to form an opening 602 through the dielectric protective layer 504a and gate layer 502a to the pedestal dielectric layer 202a. The opening 602 is in the BJT region 104. The opening 602 is defined, at least in part, by sidewalls 604, 606 of the gate layer 502a (and further by corresponding sidewalls of the dielectric protective layer 504a, which are not indicated by a reference numeral). The sidewall 604 of the gate layer 502a is over the pedestal dielectric layer 202a and the isolation structure 122 in the BJT region 104. The sidewall 606 of the gate layer 502a is over the pedestal dielectric layer 202a in the BJT region 104. As will be shown subsequently, the BJT is formed through the opening 602 through the gate layer 502a. The dielectric protective layer 504 and gate layer 502 may be etched using appropriate photolithography and etching processes. For example, an anisotropic etch, such as an RIE, may be implemented.

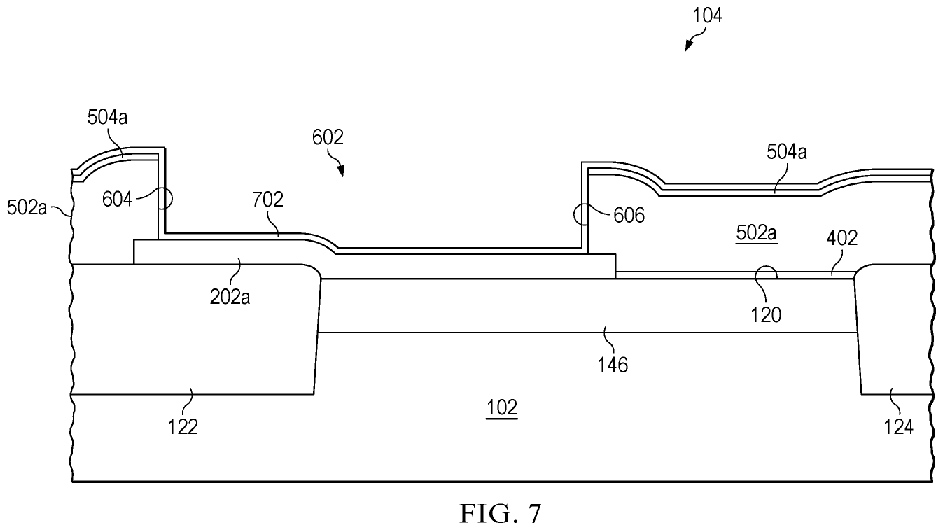

Referring to FIG. 7, a hardmask layer 702 is formed conformally over the semiconductor substrate 102. The hardmask layer 702 is conformally over the dielectric protective layer 504a, along the sidewalls 604, 606, and over the pedestal dielectric layer 202a exposed through the opening 602. In some examples, the hardmask layer 702 is or includes silicon nitride deposited by CVD, although other hardmask (e.g., dielectric) materials and/or other deposition processes may be used in other examples.

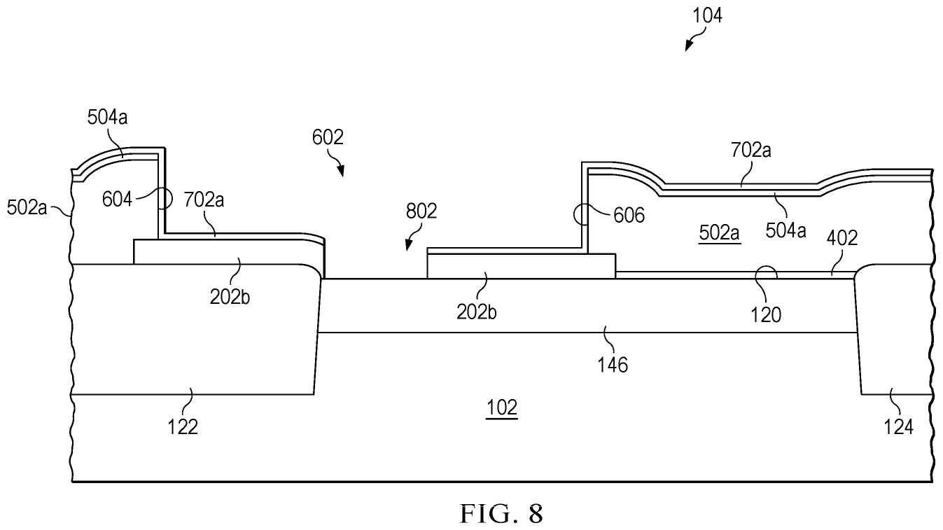

Referring to FIG. 8, the hardmask layer 702 and the pedestal dielectric layer 202a are etched to form a collector opening 802 through the hardmask layer 702a and the pedestal dielectric layer 202b. The hardmask layer 702 and the pedestal dielectric layer 202a are etched through the opening 602 to form the collector opening 802. The upper surface 120 of the semiconductor substrate 102 is exposed through the collector opening 802. The collector opening 802 generally extends from proximate to (or some lateral distance from) the isolation structure 122 laterally away from the isolation structure 122 in the BJT region 104. The hardmask layer 702 and the pedestal dielectric layer 202a may be etched using appropriate photolithography and etching processes. For example, an anisotropic etch, such as an RIE, may be implemented.

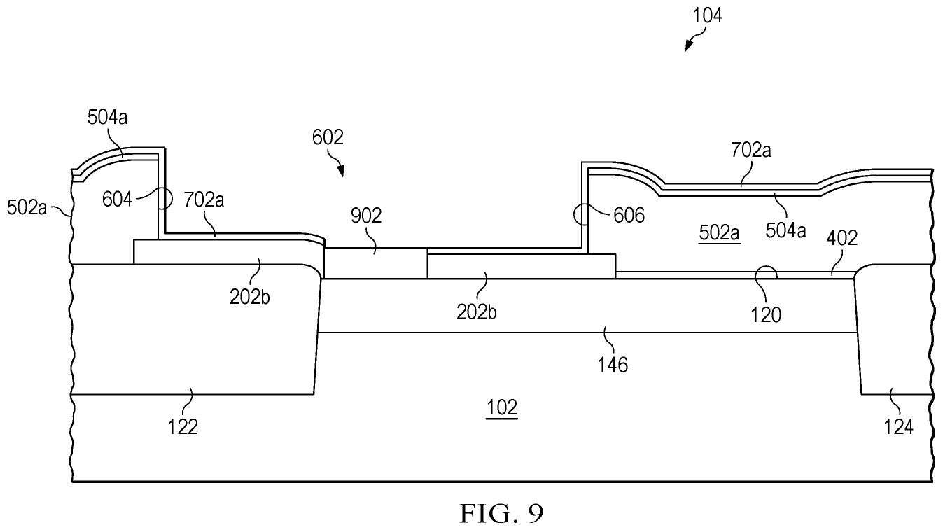

Referring to FIG. 9, a collector layer 902 is formed over (e.g., on) the upper surface 120 of the semiconductor substrate 102 and in the collector opening 802. In some examples, the collector layer 902 is or includes a semiconductor layer doped with an n-type dopant (e.g., a same dopant type as the n-type doped sub-collector diffusion region 146). In some examples, the collector layer 902 is or includes silicon. In some examples, the collector layer 902 is doped with an n-type dopant with a concentration in a range from 1×10¹⁹ cm⁻³ to 1×10²¹ cm⁻³. The collector layer 902 may be epitaxially grown on the upper surface 120 of the semiconductor substrate 102. The collector layer 902 may be epitaxially grown by a selective epitaxial growth process in some examples. The epitaxial growth of the collector layer 902 on the upper surface 120 of the semiconductor substrate 102 may result in the collector layer 902 being monocrystalline. Further, the collector layer 902 may be in situ doped during the epitaxial growth process (e.g., the selective epitaxial growth process). The epitaxial growth process may be a CVD process, such as a low pressure CVD (LPCVD), reduced pressure CVD (RPCVD), metal organic CVD (MOCVD), or the like. Other materials, dopant type, dopant concentration, and/or deposition process may be implemented.

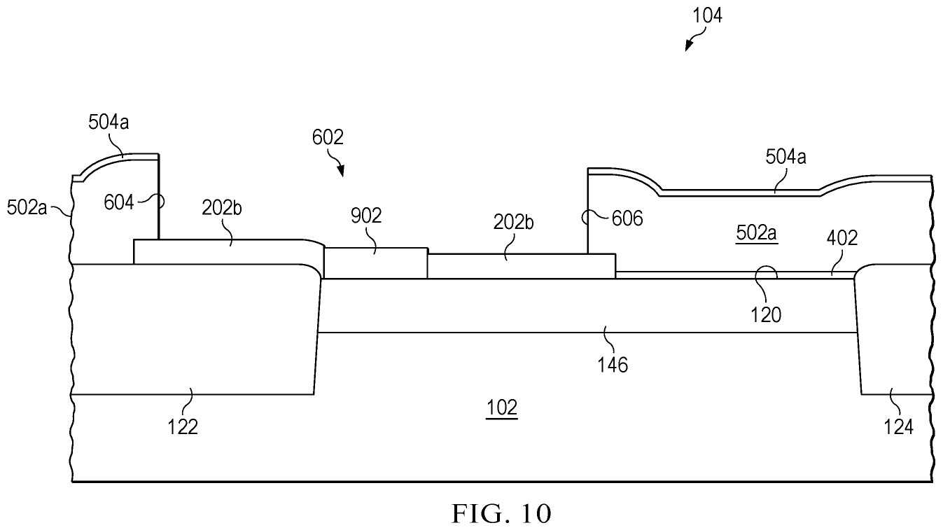

Referring to FIG. 10, the hardmask layer 702a is removed. The hardmask layer 702a may be removed using an etch selective to the material of the hardmask layer 702a, which may be a wet etch process. For example, when the hardmask layer 702a is silicon nitride, the hardmask layer 702a may be removed using a wet etch process that includes phosphoric acid (H₃PO₄).

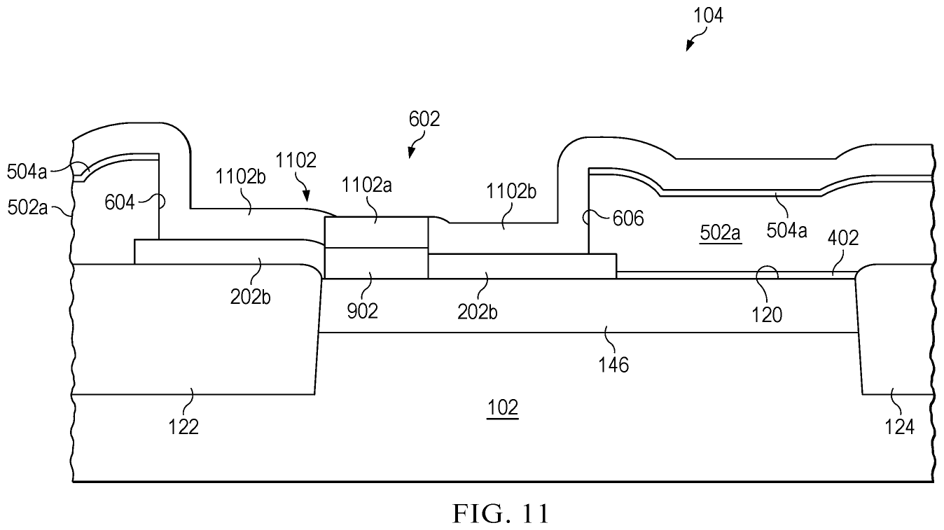

Referring to FIG. 11, a base layer 1102 is formed over the collector layer 902. The base layer 1102 includes a monocrystalline base layer 1102a and a polycrystalline base layer 1102b. The monocrystalline base layer 1102a and polycrystalline base layer 1102b together form the base layer 1102. In some examples, the base layer 1102 is or includes a semiconductor layer doped with a p-type dopant (e.g., an opposite dopant type as the collector layer 902). In some examples, the base layer 1102 is or includes silicon germanium. In some examples, the base layer 1102 is doped with a p-type dopant with a concentration in a range from 1×10¹⁷ cm⁻³ to 1×10²¹ cm⁻³. The base layer 1102 may also be doped with carbon (C) to prevent or reduce diffusion of the p-type dopant. The base layer 1102 may be epitaxially grown on the collector layer 902, the pedestal dielectric layer 202b, the gate layer 502a (e.g., sidewalls 604, 606), and the dielectric protective layer 504a. The base layer 1102 may be epitaxially grown by a non-selective epitaxial growth process in some examples. The non-selective epitaxial growth process grows the monocrystalline base layer 1102a from the collector layer 902 and grows the polycrystalline base layer 1102b on other amorphous or polycrystalline surfaces, such as the pedestal dielectric layer 202b. The monocrystalline base layer 1102a may meet the polycrystalline base layer 1102b at a facet that is not specifically illustrated. The non-selective deposition of the base layer 1102 forms the base layer 1102 conformally in the opening 602 and on the dielectric protective layer 504a outside of the opening 602. The base layer 1102 may be in situ doped during the epitaxial growth process. The base layer 1102 (e.g., the monocrystalline base layer 1102a and polycrystalline base layer 1102b each) may further include multiple sub-layers, such as a nucleation sub-layer of the same material as the collector layer 902, an undoped sub-layer, a doped sub-layer, and a cap sub-layer of the same material of the emitter layer (described subsequently). The epitaxial growth process may be a CVD process, such as LPCVD, RPCVD, MOCVD, or the like. Other materials, dopant type, dopant concentration, and/or deposition process may be implemented.

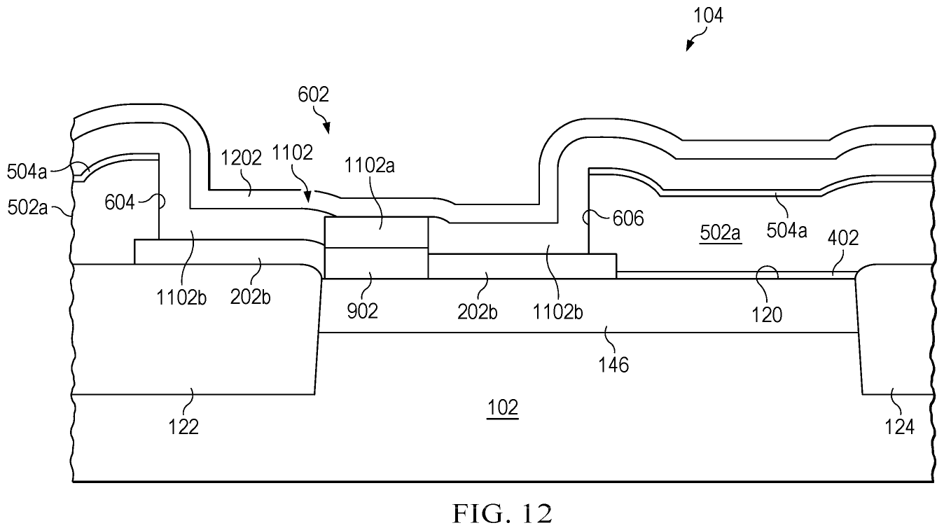

Referring to FIG. 12, an inverse mask layer 1202 is formed conformally over the base layer 1102. In some examples, the inverse mask layer 1202 is a layer of a single material, and in other examples, the inverse mask layer 1202 includes sub-layers of different materials. In some examples, the inverse mask layer 1202 is a single layer of silicon nitride. In some examples, the inverse mask layer 1202 includes a first sub-layer over the base layer 1102 and a second sub-layer over the first base layer, where the first base sub-layer is silicon oxide and the second base layer is silicon nitride. The inverse mask layer 1202 may be deposited by CVD. Other mask materials (e.g., dielectric materials) and/or other deposition processes may be used in other examples.

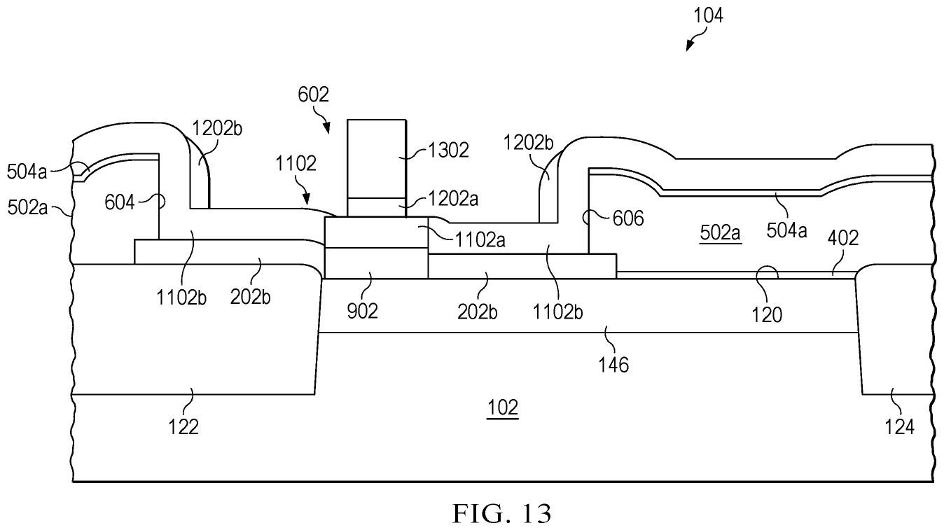

Referring to FIG. 13, the inverse mask layer 1202 is patterned into an inverse mask 1202a. The inverse mask 1202a masks an area such that, in a subsequent epitaxial growth process, a raised base layer is not formed in the masked area. The inverse mask 1202a may therefore permit an opening to be formed through the raised base layer, as described subsequently. The inverse mask layer 1202 may be patterned using appropriate photolithography (e.g., using a photoresist 1302) and etching processes. For example, an anisotropic etch, such as an RIE, may be implemented. Residual masks 1202b may remain on respective sidewall surfaces following the patterning.

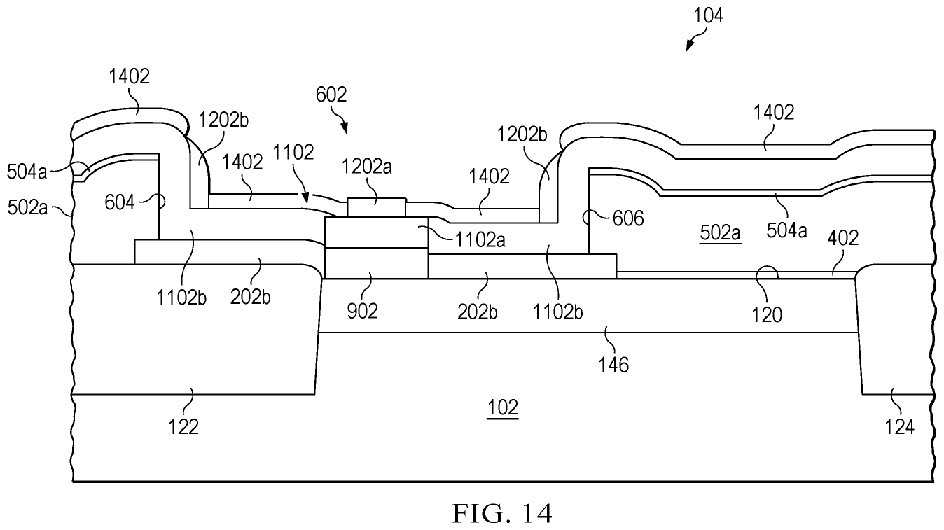

Referring to FIG. 14, a raised base layer 1402 is formed over the base layer 1102. The raised base layer 1402 includes at least a polycrystalline raised base layer on the polycrystalline base layer 1102b. The raised base layer 1402 may include a monocrystalline raised base layer. If the monocrystalline base layer 1102a is exposed, e.g., is not masked by the inverse mask 1202a, the raised base layer 1402 may include a monocrystalline portion on the monocrystalline base layer 1102a. In some examples, the raised base layer 1402 is or includes a semiconductor layer doped with a p-type dopant (e.g., a same dopant type as the base layer 1102). In some examples, the raised base layer 1402 is or includes silicon. In some examples, the raised base layer 1402 is doped with a p-type dopant with a concentration in a range from 1×10¹⁹ cm⁻³ to 1×10²¹ cm⁻³. The raised base layer 1402 may be epitaxially grown on the base layer 1102. The raised base layer 1402 may be epitaxially grown by a selective epitaxial growth process in some examples. The selective deposition of the raised base layer 1402 forms the raised base layer 1402 conformally on crystalline (e.g., polycrystalline and monocrystalline) surfaces in and outside of the opening 602 (e.g., on the base layer 1102). The selective deposition of the raised base layer 1402 prevents the raised base layer 1402 from be deposited on non-crystalline (e.g., amorphous) surfaces, such as the inverse mask 1202a and any residual masks 1202b. Hence, the inverse mask 1202a may define sidewalls of the raised base layer 1402. Further, the raised base layer 1402 may be in situ doped during the epitaxial growth process (e.g., the selective epitaxial growth process). The epitaxial growth process may be a CVD process, such as LPCVD, RPCVD, MOCVD, or the like. Other materials, dopant type, dopant concentration, and/or deposition process may be implemented.

The raised base layer 1402 in the opening 602 has a substantially uniform thickness. Generally, a thickness of a given layer is in a direction normal to a tangent plane of the underlying surface on which the given layer is formed. However, in some instances, such as with a conformal deposition, a direction normal to a tangent plane of the underlying surface may not be a thickness, such as where a thickness from another tangent plane intersects that direction normal, like at a corner. The substantially uniform thickness of the raised base layer 1402 in the opening 602 in this example results from physically unimpeded or physically unrestricted vertical growth of the raised base layer 1402. No physical structure impedes or restricts vertical growth of the raised base layer 1402 throughout its deposition within the opening 602. In some instances, slight variation (e.g., non-substantial) of the thickness may occur due to defects or crystalline planes at or near where a monocrystalline portion of the raised base layer 1402 (e.g., growing from the monocrystalline base layer 1102a) meets a polycrystalline portion of the raised base layer 1402 (e.g., growing from the polycrystalline base layer 1102b). Further, the raised base layer 1402 in the opening 602 has an upper surface that is substantially continuous. The absence of a physical structure impeding or restricting vertical growth of the raised base layer 1402 throughout its deposition within the opening 602 permits the upper surface to be substantially continuous. Some non-substantial discontinuity of the upper surface of the raised base layer 1402 in the opening 602 may occur at or near where a monocrystalline portion of the raised base layer 1402 and a monocrystalline portion of the raised base layer 1402 meet.

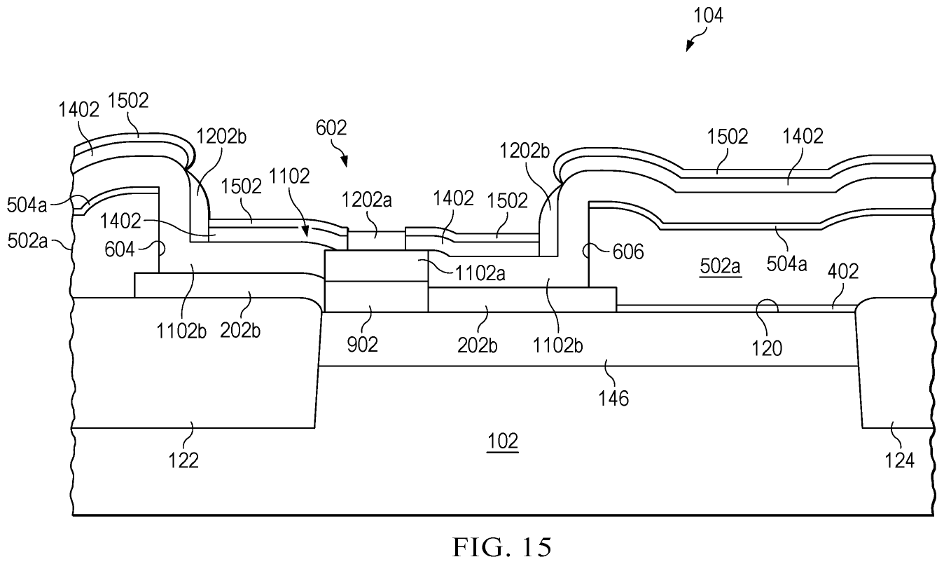

Referring to FIG. 15, a dielectric protective layer 1502 is formed on the raised base layer 1402. The dielectric protective layer 1502 is selectively formed on the raised base layer 1402 and not on the inverse mask 1202a. The selective formation may permit the inverse mask 1202a to be exposed for subsequent removal by a selective etch process (e.g., without masking by using photolithography). The dielectric protective layer 1502 has respective sidewalls that align with corresponding sidewalls of the raised base layer 1402 (e.g., which were defined by the inverse mask 1202a). In some examples, the dielectric protective layer 1502 is an oxide formed by oxidizing (e.g., by ISSG) the raised base layer 1402. In some examples, the oxidation process for forming the dielectric protective layer 1502 is a low temperature oxidation, such as with a temperature not exceeding 700° C., such as within a range from 600° C. to 700° C. A low temperature process may reduce diffusion and/or outgassing of dopants from, e.g., the raised base layer 1402. Other materials and/or selective formation processes may be implemented.

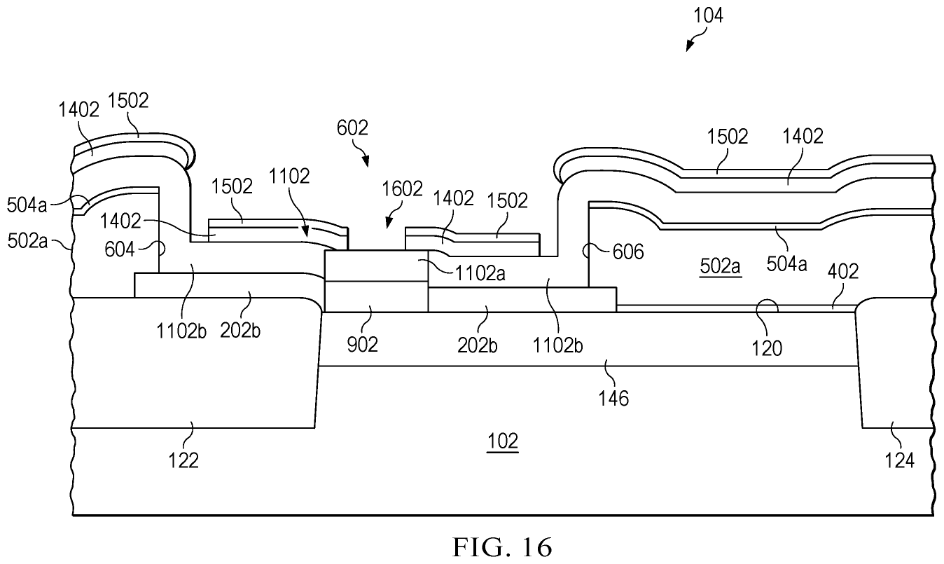

Referring to FIG. 16, the inverse mask 1202a is removed thereby forming an opening 1602 through the raised base layer 1402 to the monocrystalline base layer 1102a. The inverse mask 1202a may be removed using an etch selective to the material of the inverse mask 1202a, which may be a wet etch process. For example, when the inverse mask 1202a is silicon nitride, the inverse mask 1202a may be removed using a wet etch process that includes phosphoric acid (H₃PO₄). Any residual mask 1202b may be removed by the removal of the inverse mask 1202a.

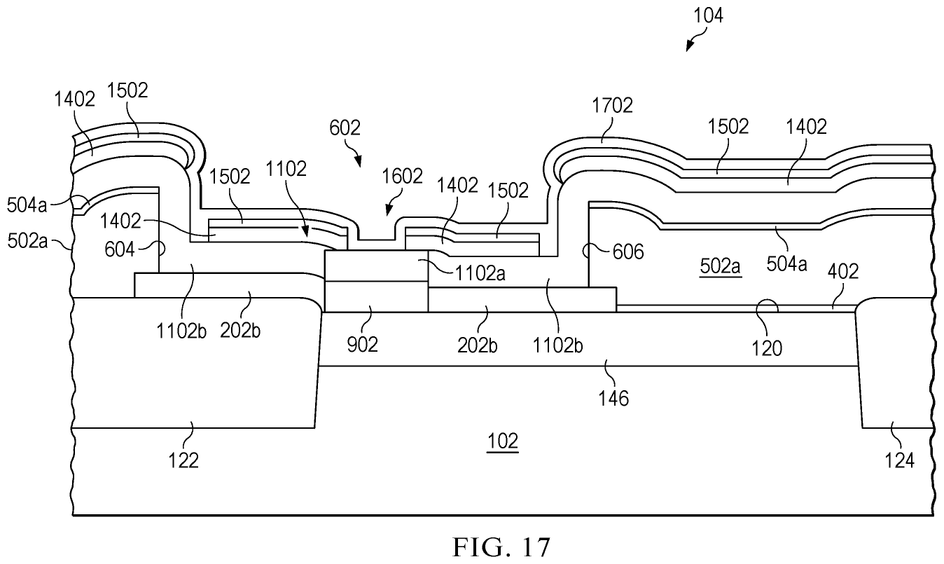

Referring to FIG. 17, a dielectric spacer layer 1702 is formed conformally, among other things, over the dielectric protective layer 1502 and in the opening 1602. In the opening 1602, the dielectric spacer layer 1702 is formed along the sidewalls of the raised base layer 1402 (e.g., which were defined by the inverse mask 1202a) and the dielectric protective layer 1502 that are aligned and define the opening 1602, and the dielectric spacer layer 1702 is formed over the monocrystalline base layer 1102a that defines a bottom surface of the opening 1602. In some examples, dielectric spacer layer 1702 is silicon nitride. The dielectric spacer layer 1702 may be deposited by CVD. Other dielectric materials and/or other deposition processes may be used in other examples.

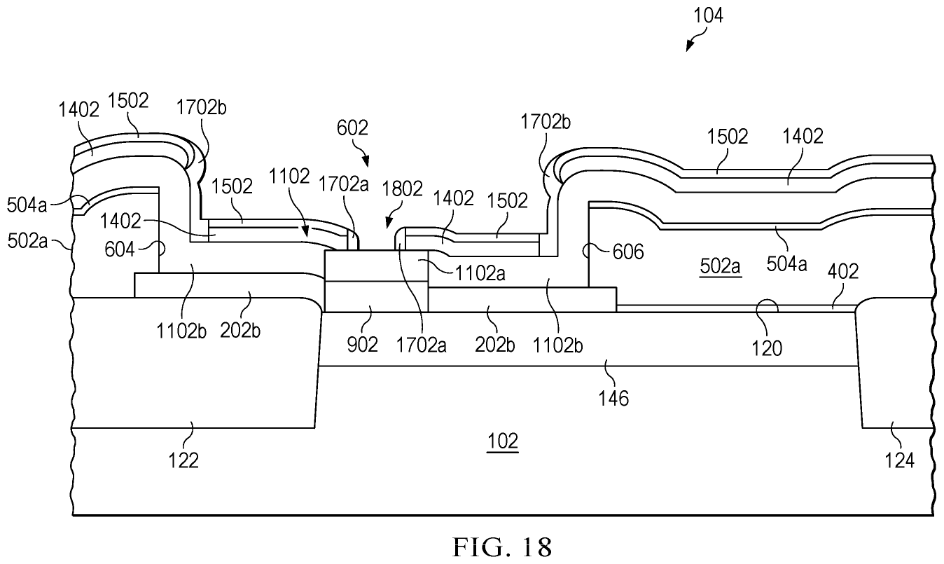

Referring to FIG. 18, the dielectric spacer layer 1702 is anisotropically etched to form emitter dielectric spacers 1702a along the sidewalls that define the opening 1602. The emitter dielectric spacers 1702a constrict the opening 1602 to form an emitter opening 1802. The monocrystalline base layer 1102a is exposed through the emitter opening 1802 and between the emitter dielectric spacers 1702a. Additionally, residual dielectric spacers 1702b may remain on other vertical surfaces. The anisotropic etch may be an RIE, for example, which may be followed by a wet clean, including using dilute hydrofluoric acid (dHF).

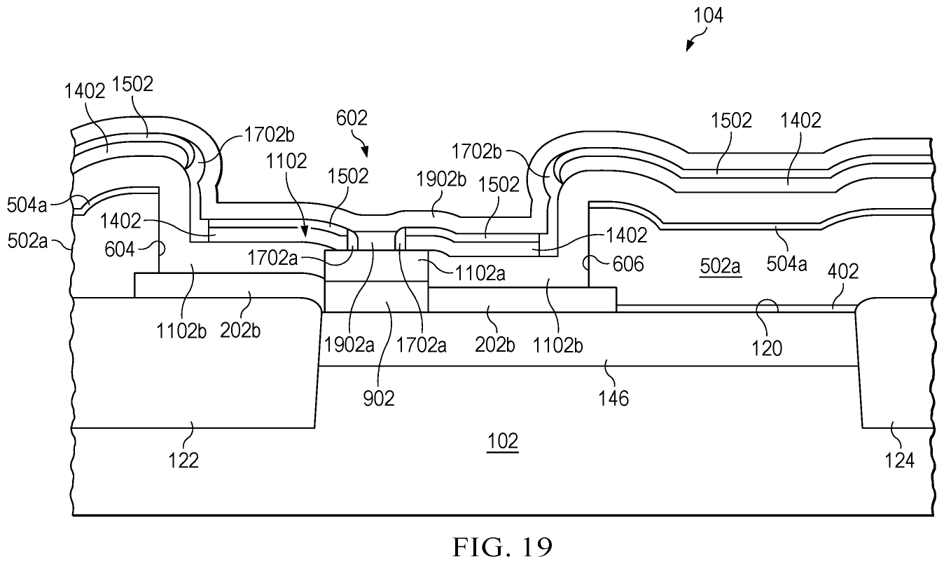

Referring to FIG. 19, an emitter layer 1902 is formed over the base layer 1102 (e.g., on the monocrystalline base layer 1102a), the emitter dielectric spacers 1702a, and the dielectric protective layer 1502. The emitter layer 1902 includes a monocrystalline emitter layer 1902a and a polycrystalline emitter layer 1902b. The monocrystalline emitter layer 1902a and polycrystalline emitter layer 1902b together form the emitter layer 1902. In some examples, the emitter layer 1902 is or includes a semiconductor layer doped with an n-type dopant (e.g., an opposite dopant type from the base layer 1102). In some examples, the emitter layer 1902 is or includes silicon. In some examples, the emitter layer 1902 is doped with an n-type dopant with a concentration in a range from 1×10¹⁹ cm⁻³ to 1×10²¹ cm⁻³. The emitter layer 1902 may be epitaxially grown on the base layer 1102 (e.g., the monocrystalline base layer 1102a) exposed through the emitter opening 1802, the emitter dielectric spacers 1702a, the dielectric protective layer 1502, and any residual dielectric spacers 1702b. The emitter layer 1902 may be epitaxially grown by a non-selective epitaxial growth process in some examples. The non-selective epitaxial growth process grows the monocrystalline emitter layer 1902a from the monocrystalline base layer 1102a and grows the polycrystalline emitter layer 1902b on other amorphous or polycrystalline surfaces, such as the emitter dielectric spacers 1702a and the dielectric protective layer 1502. The monocrystalline emitter layer 1902a may meet the polycrystalline emitter layer 1902b at a facet that is not specifically illustrated. The non-selective deposition of the emitter layer 1902 forms the emitter layer 1902 conformally in the opening 602 and on the dielectric protective layer 1502 outside of the opening 602. The emitter layer 1902 may be in situ doped during the epitaxial growth process. The epitaxial growth process may be a CVD process, such as LPCVD, RPCVD, MOCVD, or the like. Other materials, dopant type, dopant concentration, and/or deposition process may be implemented.

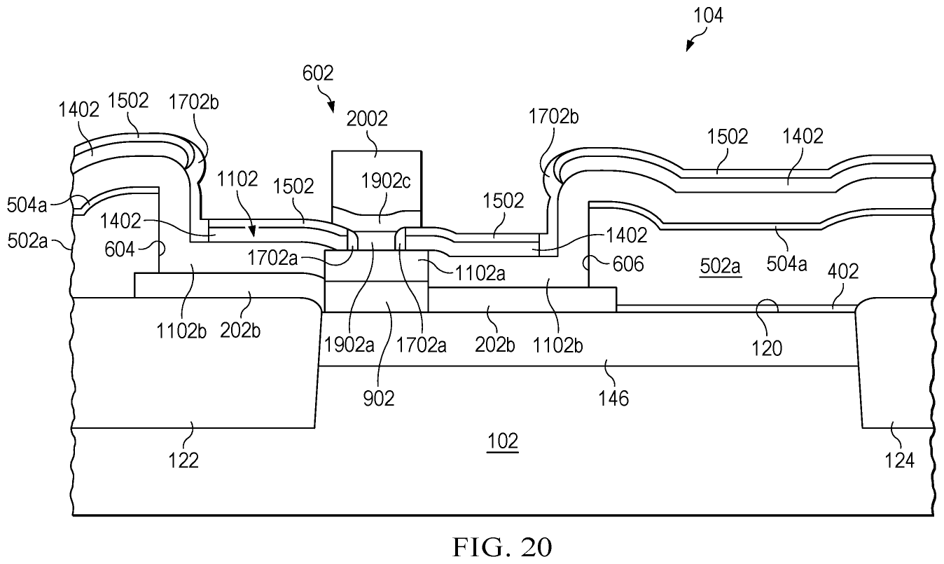

Referring to FIG. 20, the polycrystalline emitter layer 1902b is patterned into a polycrystalline emitter layer 1902c. Patterning the polycrystalline emitter layer 1902b forms sidewalls of the polycrystalline emitter layer 1902c within the opening 602 and over the dielectric protective layer 1502. The polycrystalline emitter layer 1902b may be patterned using appropriate photolithography (e.g., using a photoresist 2002) and etching processes. For example, an anisotropic etch (e.g., an RIE) and/or isotropic etch (e.g., a wet etch), may be implemented.

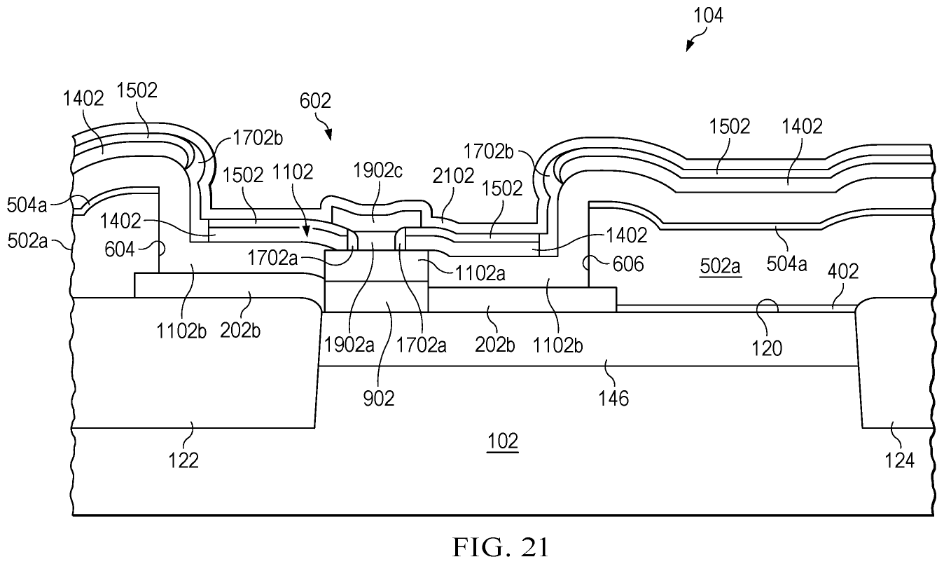

Referring to FIG. 21, a dielectric protective layer 2102 is conformally formed, among other things, over the emitter layer 1902 (e.g., the polycrystalline emitter layer 1902c) and the dielectric protective layer 1502. In some examples, the dielectric protective layer 2102 is silicon oxide (e.g., a TEOS oxide) deposited by CVD, although other dielectric materials and/or other deposition processes may be used in other examples.

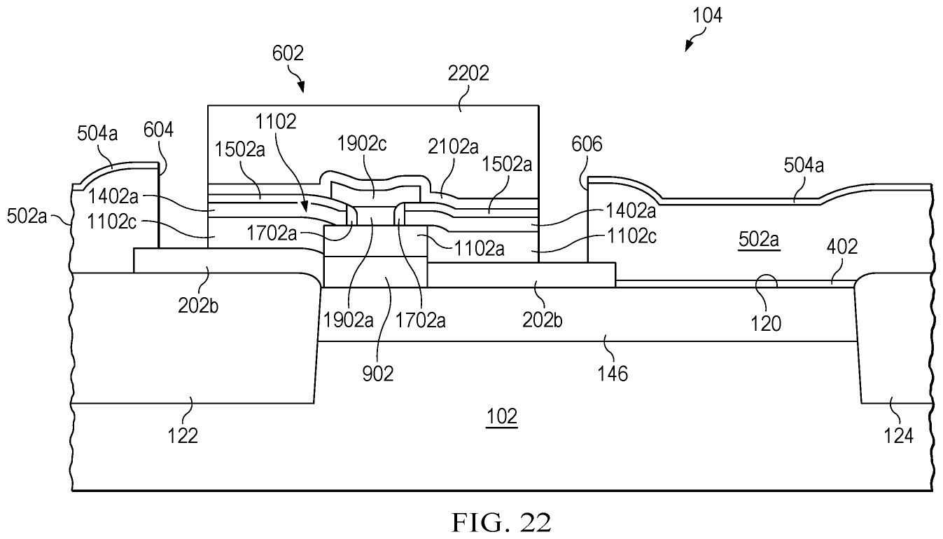

Referring to FIG. 22, the dielectric protective layer 2102, the dielectric protective layer 1502, the raised base layer 1402, and the base layer 1102 (e.g., the polycrystalline base layer 1102b) are patterned. The raised base layer 1402 and the polycrystalline base layer 1102b are patterned to remain as the raised base layer 1402a and polycrystalline base layer 1102c within the opening 602. Similarly, the dielectric protective layer 2102 and the dielectric protective layer 1502 are patterned to remain as the dielectric protective layer 2102a and the dielectric protective layer 1502a within the opening 602. Any residual dielectric spacer 1702b may also be removed by the patterning. The dielectric protective layer 2102, the dielectric protective layer 1502, the raised base layer 1402, and the base layer 1102 outside of the opening 602, and more generally, outside of the BJT region 104, are removed by the patterning. Hence, the base layer 1102 and raised base layer 1402 are removed from the sidewalls 604, 606 of the gate layer 502a and from over the dielectric protective layer 504a. The pedestal dielectric layer 202b extends laterally from the polycrystalline base layer 1102c over the isolation structure 122 and extends laterally from the polycrystalline base layer 1102c over the upper surface 120 of the semiconductor substrate 102 in the BJT region 104. The dielectric protective layer 2102, dielectric protective layer 1502, raised base layer 1402, and base layer 1102 may be patterned using appropriate photolithography (e.g., using photoresist 2202) and etching processes. For example, an anisotropic etch, such as an RIE, may be implemented.

Generally, forming the raised base layer 1402a and the emitter layer 1902 as described may result in simpler processing. Fewer processing steps may be implemented by forming the raised base layer 1402 before the emitter layer 1902 compared to processing in which a raised base layer is formed after forming an emitter layer. Additionally, undercutting layers by etching underlying layers (for forming a raised base layer after forming an emitter) may be obviated, which undercutting may be difficult to control and may have difficult endpoint detection. The described processing may permit scaling to smaller device sizes and thinner films while avoiding some processing difficulties. Additionally, patterning the emitter dielectric spacers 1702a to form the emitter opening 1802 may achieve additional shrinkage of the emitter opening 1802 and may have improved line width roughness over a photolithography process for patterning an emitter opening.

Although not illustrated in the figures, processing may be included in some examples to form an nFET and/or a pFET; other examples may omit such processing. Description of such processing is provided below as an example. In subsequent processing for forming an nFET and/or a pFET, a lower thermal budget may be implemented. The lower thermal budget may mitigate against relaxation of the monocrystalline base layer 1102a when the monocrystalline base layer 1102a is a material dissimilar from the collector layer 902. The lower thermal budget may also mitigate against diffusion of dopants between the collector layer 902, base layer 1102, and/or emitter layer 1902. Examples of such thermal processing with a lower thermal budget are provided below.

A hardmask layer is conformally formed over the dielectric protective layer 504a and in the opening 602. The hardmask layer is conformally over the dielectric protective layer 504a, along the sidewalls 604, 606, over the pedestal dielectric layer 202b, along sidewalls of the base layer 1102 (e.g., polycrystalline base layer 1102c), raised base layer 1402a, dielectric protective layer 1502a, and dielectric protective layer 2102a, and over the dielectric protective layer 2102a. In some examples, the hardmask layer is or includes silicon nitride deposited by CVD, although other hardmask (e.g., dielectric) materials and/or other deposition processes may be used in other examples.

The gate layer 502a is patterned into respective gate electrodes for the nFET and the pFET, and the gate dielectric layer 402 is patterned into respective gate dielectric layers for the nFET and the pFET. The hardmask layer is patterned corresponding to the pattern of the gate electrodes and as a mask in the BJT region 104. In the BJT region 104, the hardmask layer, as patterned, is over the dielectric protective layer 2102a and is along sidewalls of the dielectric protective layer 2102a, dielectric protective layer 1502a, raised base layer 1402a, and polycrystalline base layer 1102c. As patterned, the hardmask layer may have a sidewall over the pedestal dielectric layer 202b between the sidewall 604 and a corresponding sidewall of the polycrystalline base layer 1102c and may have another sidewall over the pedestal dielectric layer 202b between the sidewall 606 and a corresponding sidewall of the polycrystalline base layer 1102c. Using the patterned hardmask layer as a mask, the gate layer 502a and the gate dielectric layer 402 are patterned. The hardmask layer may be patterned using appropriate photolithography and etching processes, and the gate layer 502a and the gate dielectric layer 402 may be patterned using an appropriate etching process. For example, an anisotropic etch, such as an RIE, may be implemented. For the nFET, the gate electrode is over (e.g., on) the gate dielectric layer in the nFET region, and for the pFET, the gate electrode is over (e.g., on) the gate dielectric layer in the pFET region. Patterning the gate layer 502a and the gate dielectric layer 402 removes the gate layer 502a and the gate dielectric layer 402 from the illustrated BJT region 104, and more specifically, removes the gate layer 502a and the gate dielectric layer 402 from the upper surface 120 of the semiconductor substrate 102 in the BJT region 104. Thereafter, the patterned hardmask layer and remaining dielectric protective layer 504a are removed, such as by wet etches selective to the material of those layers. For example, when the hardmask layer is silicon nitride, a wet etch including phosphoric acid may remove the hardmask layer, and when the dielectric protective layer 504a is silicon oxide, a wet etch including diluted hydrochloric acid may remove the dielectric protective layer 504a.

After removing the hardmask layer and the dielectric protective layer 504a, a protective oxide layer may be formed on the gate electrodes. The protective oxide layer may be formed by an oxidation process, such as ISSG. In some examples with a lower thermal budget, the oxidation process may be performed at 750° C. or less for 5 seconds or less.

First gate dielectric spacers are formed along sidewalls of the gate electrodes. The first gate dielectric spacers may be formed by depositing a layer of the material of the first gate dielectric spacers conformally over the semiconductor substrate 102 and anisotropically etching the layer such that the first gate dielectric spacers remain. The material of the first gate dielectric spacers may be any appropriate dielectric material, such as silicon nitride, silicon oxynitride, silicon carbon nitride, the like, or a combination thereof. The layer may be deposited by CVD, PECVD, atomic layer deposition (ALD), or the like. The formation of the first gate dielectric spacers may further form residual dielectric spacers on sidewalls of components in the BJT region 104. For example, residual dielectric spacers may be on respective sidewalls the polycrystalline base layer 1102c and raised base layer 1402a, among others.

P-type lightly doped drain regions (LDDs) and n-type LDDs are formed in the semiconductor substrate 102 in the pFET region and the nFET region, respectively. The p-type LDDs are in the semiconductor substrate 102 on laterally opposing sides of the gate electrode of the pFET, and the n-type LDDs are in the semiconductor substrate 102 on laterally opposing sides of the gate electrode of the nFET. The p-type LDDs may be formed by masking (e.g., by a photoresist using photolithography) the BJT region 104 and nFET region and implanting a p-type dopant into the semiconductor substrate 102 in the pFET region. The n-type LDDs may be formed by masking (e.g., by a photoresist using photolithography) the BJT region 104 and pFET region and implanting an n-type dopant into the semiconductor substrate 102 in the nFET region. A concentration of the p-type dopant of the p-type LDDs is greater than the concentration of the n-type dopant of the n-type doped well in the pFET region, and a concentration of the n-type dopant of the n-type LDDs is greater than the concentration of the p-type dopant of the p-type doped well in the nFET region. In some examples, the p-type LDDs are doped with a p-type dopant with a concentration in a range from 1×10¹⁹ cm⁻³ to 1×10²¹ cm⁻³, and the n-type LDDs are doped with an n-type dopant with a concentration in a range from 1×10¹⁹ cm⁻³ to 1×10²¹ cm⁻³. Other doping concentrations may be implemented.

After performing implantation(s) to form the p-type LDDs and the n-type LDDs, an activation anneal may be performed. In some examples with a lower thermal budget, the activation anneal includes a laser anneal following the first implantation (e.g., of n-type or p-type dopants) and a spike anneal reaching 930° C. or less following the second implantation (e.g., of the other of the n-type or p-type dopants).

Second gate dielectric spacers are formed along sidewalls of the first gate dielectric spacers. The second gate dielectric spacers may be formed by depositing a layer of the material of the second gate dielectric spacers conformally over the semiconductor substrate 102 and anisotropically etching the layer such that the second gate dielectric spacers remain. The material of the second gate dielectric spacers may be any appropriate dielectric material, such as silicon nitride, silicon oxynitride, silicon carbon nitride, the like, or a combination thereof. The layer may be deposited by CVD, PECVD, ALD, or the like. The formation of the second gate dielectric spacers may further form residual dielectric spacers on sidewalls of components in the BJT region 104.

Embedded stressors are formed in the semiconductor substrate 102 on opposing lateral sides of the gate electrode in the pFET region. To form the embedded stressors, respective recesses are formed in the semiconductor substrate 102. To form the recesses, a conformal hardmask layer is formed over the semiconductor substrate 102 in the BJT region 104 and nFET region. The conformal hardmask layer may be or include silicon nitride, silicon oxynitride, the like, or a combination thereof. The conformal hardmask layer may be formed by conformally depositing and patterning the conformal hardmask layer. The conformal hardmask layer may be deposited by CVD, PECVD, ALD, or the like. The conformal hardmask layer may be patterned using photolithography and etching processes. Then, stressor recesses are formed in the semiconductor substrate 102 on opposing lateral sides of the gate electrode in the pFET region. The stressor recesses are etched in the semiconductor substrate 102 where the embedded stressors are to be formed. The stressor recesses may be formed using any appropriate etch process, which may be a wet or dry etch process. The etch process may be anisotropic and selective to (e.g., etching preferentially) a crystalline plane of the semiconductor substrate 102. The embedded stressors are then formed in the stressor recesses. The embedded stressors may be formed using a selective epitaxial growth process. The embedded stressors may be formed using MOCVD, molecular beam epitaxy (MBE), LPCVD, or another epitaxy process. The embedded stressors may be or include, for example, silicon germanium (SiGe). After forming the embedded stressors, the conformal hardmask layer is removed. The conformal hardmask layer may be removed by an etch process selective to the material of the conformal hardmask layer, which may be a wet or dry etch process.

A stress memorization technique may be implemented, such as in the nFET region. A stressor dielectric layer is formed over the semiconductor substrate 102, the gate electrode of the nFET, and corresponding gate dielectric spacers in the nFET region. The stressor dielectric layer may be or include silicon nitride, the like, or a combination thereof. The stressor dielectric layer may be formed by conformally depositing and patterning the stressor dielectric layer. The stressor dielectric layer may be deposited by CVD, PECVD, ALD, or the like. The stressor dielectric layer may be patterned using photolithography and etching processes. An anneal process is performed with the stressor dielectric layer in the nFET region. The anneal process may be or include a millisecond laser anneal for dopant activation and a spike rapid thermal anneal (RTA) with reduced thermal budget. A spike RTA may be at peak temperature for approximately 1 second and rapidly decrease in temperature to minimize dopant diffusion. The anneal process permits the lattice structure of the semiconductor substrate 102 to conform due to the stress induced by the stressor dielectric layer. After the anneal process, the stressor dielectric layer is removed. The stressor dielectric layer may be removed by an etch process selective to the material of the stressor dielectric layer, which may be a wet or dry etch process.

N-type source/drain (NSD) regions and p-type source/drain (PSD) regions are formed in the semiconductor substrate 102. The NSD regions are formed in the p-type doped well in the semiconductor substrate 102 in the nFET region. The NSD regions are on opposing lateral sides of the gate electrode in the nFET region, with the n-type LDDs therebetween. The PSD regions are formed in the pFET region and may be formed in the embedded stressors and/or may further extend below the embedded stressors into the n-type doped well in the semiconductor substrate 102 in the pFET region. The PSD regions are on opposing lateral sides of the gate electrode in the pFET region, with the p-type LDDs therebetween.

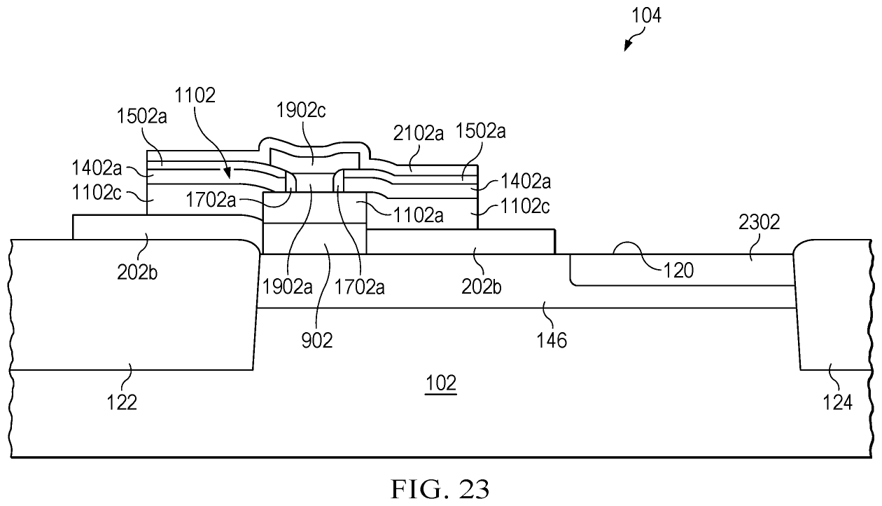

An n-type collector contact region 2302 is formed in the semiconductor substrate 102 in the BJT region 104, as shown in FIG. 23. The n-type collector contact region 2302 is formed in the BJT region 104 in the n-type doped sub-collector diffusion region 146 in the semiconductor substrate 102. The n-type collector contact region 2302 is laterally between the pedestal dielectric layer 202b and the isolation structure 124. The n-type collector contact region 2302 may be formed simultaneously with the NSD regions.

An implantation is performed to form the n-type collector contact region 2302 and the NSD regions. The n-type collector contact region 2302 and the NSD regions may be formed by masking (e.g., by a photoresist using photolithography) the pFET region and the base layer 1102, raised base layer 1402a, and emitter layer 1902 in the BJT region 104 and implanting an n-type dopant into the semiconductor substrate 102 in the nFET region and exposed portion of the BJT region 104. An implantation is performed to form the PSD regions. The PSD regions may be formed by masking (e.g., by a photoresist using photolithography) the BJT region 104 and the nFET region and implanting a p-type dopant into the semiconductor substrate 102 in the pFET region.

A concentration of the n-type dopant of the n-type collector contact region 2302 is greater than the concentration of the n-type dopant of the n-type doped sub-collector diffusion region 146. A concentration of the n-type dopant of the NSD regions is greater than the concentration of the n-type dopant of the n-type LDDs and the concentration of the p-type dopant of the p-type doped well in the nFET region. A concentration of the p-type dopant of the PSD regions is greater than the concentration of the p-type dopant of the p-type LDDs and the concentration of the n-type dopant of the n-type doped well in the pFET region. In some examples, the n-type collector contact region 2302 and the NSD regions are doped with an n-type dopant with a concentration in a range from 1×10²⁰ cm⁻³ to 1×10²¹ cm⁻³, and the PSD regions are doped with a p-type dopant with a concentration in a range from 1×10²⁰ cm⁻³ to 1×10²¹ cm⁻³. Other doping concentrations may be implemented.

After performing the implantations to form the n-type collector contact region 2302, NSD regions, PSD regions, an activation anneal may be performed. In some examples with a lower thermal budget, the activation anneal includes a laser anneal following the first implantation (e.g., of n-type or p-type dopants) and a spike anneal reaching 1,010° C. or less following the second implantation (e.g., of the other of the n-type or p-type dopants).

Any residual dielectric spacers in the BJT region 104 may thereafter be removed. Any residual dielectric spacers in the BJT region 104 may be removed by masking (e.g., by a photoresist using photolithography) the pFET region and the nFET region and performing an etch selective to the residual dielectric spacers in the BJT region 104, which may be a wet or dry etch process. Subsequently, the semiconductor device, including the BJT region 104, may be as shown in FIG. 23.

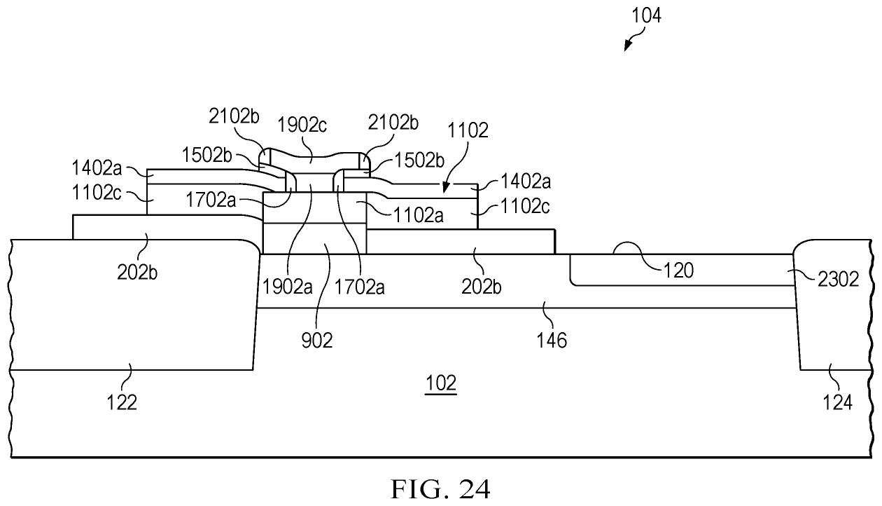

Referring to FIG. 24, the dielectric protective layer 2102a and dielectric protective layer 1502a are patterned into dielectric protective spacers 2102b and dielectric protective layer 1502b, respectively. The dielectric protective spacers 2102b remain along respective sidewalls of the polycrystalline emitter layer 1902c. The dielectric protective layer 1502b remains underlying the dielectric protective spacers 2102b and the polycrystalline emitter layer 1902c. The dielectric protective layer 2102a and dielectric protective layer 1502a may be patterned using appropriate etching processes. For example, an anisotropic etch, such as an RIE, may be implemented.

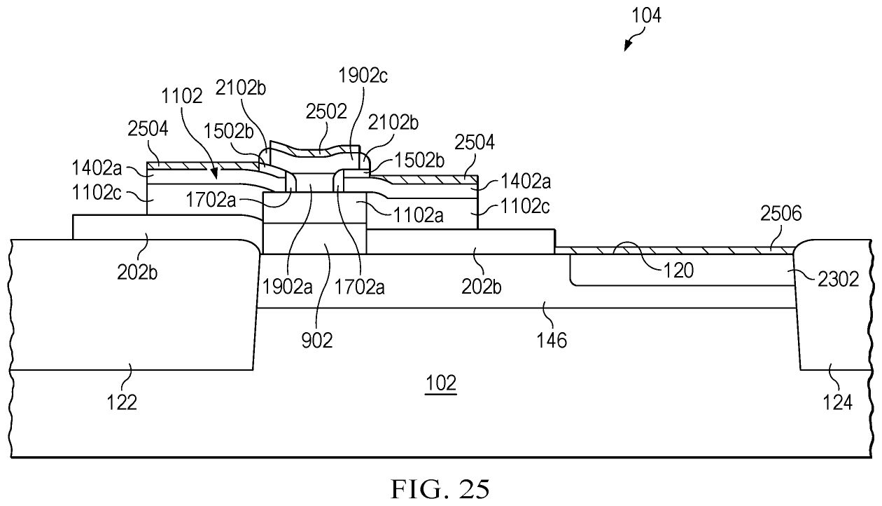

Referrring to FIG. 25, metal-semiconductor compound 2502, 2504, 2506 are formed. The metal-semiconductor compound 2502 is on the emitter layer 1902 (e.g., the polycrystalline emitter layer 1902c and/or monocrystalline emitter layer 1902a). The metal-semiconductor compound 2504 is on the raised base layer 1402a. The metal-semiconductor compound 2506 is on the upper surface 120 of the semiconductor substrate 102 at the n-type collector contact region 2302. Although not illustrated, metal-semiconductor compound may be formed in the nFET region and pFET region. Respective metal-semiconductor compound are on the embedded stressors and on the gate electrode in the pFET region. Respective metal-semiconductor compound are on the NSD regions in the semiconductor substrate 102 and on the gate electrode in the nFET region. The metal-semiconductor compound 2502, 2504, 2506 and any metal-semiconductor compound in the nFET region and pFET region may be a silicide (e.g., NiSix, TiSix, CoSix, PtSix), a germanicide, or the like.

The metal-semiconductor compound 2502, 2504, 2506 and any metal-semiconductor compound in the nFET region and pFET region may be formed by depositing a metal (e.g., Ni, Ti, Co, Pt) over the semiconductor substrate 102, such as by physical vapor deposition (PVD), CVD, or the like. The metal is reacted with a semiconductor material, such as the semiconductor material of the emitter layer 1902 (e.g., polycrystalline emitter layer 1902c and/or monocrystalline emitter layer 1902a), the semiconductor material of the raised base layer 1402a, the semiconductor material of the semiconductor substrate 102, the semiconductor material of the embedded stressors, and the semiconductor material (e.g., silicon, such as polysilicon) of the gate electrodes. An anneal process may be used to cause the metal to react with a semiconductor material. For example, a laser anneal (e.g., a millisecond laser anneal) may be used in a reduced thermal budget implementation. Any unreacted metal may be removed, such as by an etch selective to the metal.

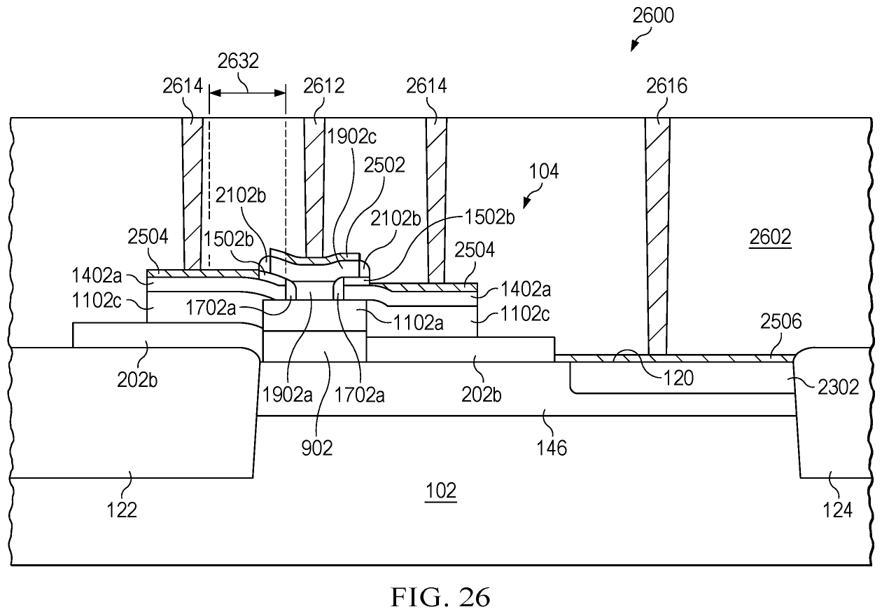

Referring to FIG. 26, a dielectric layer 2602 is formed over the semiconductor substrate 102, and contacts 2612, 2614, 2616 are formed through the dielectric layer 2602. Although not illustrated, contacts may be formed in the nFET region and pFET region. The dielectric layer 2602 may include one or more dielectric sub-layers. For example, the dielectric layer 2602 may include a conformal first dielectric sub-layer over the semiconductor substrate 102 and a second dielectric sub-layer over the first dielectric sub-layer. The conformal first dielectric sub-layer may be a stressor layer, an etch stop layer, or the like, which may be or include silicon nitride, silicon oxynitride, the like, or a combination thereof. The second dielectric sub-layer may be or include silicon oxide, silicon nitride, or the like. The dielectric layer 2602 may be or include a pre-metal dielectric (PMD), an inter-layer dielectric (ILD), or the like. The dielectric layer 2602 may be deposited using CVD, PECVD, ALD, or the like. The dielectric layer 2602 may be planarized, such as by a CMP.

The contacts 2612, 2614, 2616 and any contacts in the nFET region and pFET region extend through the dielectric layer 2602 and contact respective metal-semiconductor compound. As illustrated, the contact 2612 contacts the metal-semiconductor compound 2502; the contacts 2614 contact the metal-semiconductor compound 2504; and the contact 2616 contacts the metal-semiconductor compound 2506. The contacts 2612, 2614, 2616 and any contacts in the nFET region and pFET region may each include one or more barrier and/or adhesion layers (e.g., titanium nitride (TiN), tantalum nitride (TaN), the like, or a combination thereof) conformally in a respective opening through the dielectric layer 2602, and a fill metal (e.g., tungsten (W), copper (Cu), aluminum (Al), the like, or a combination thereof) over and/or on the barrier and/or adhesion layer(s).

To form the contacts, respective openings may be formed through the dielectric layer 2602 to the metal-semiconductor compound using appropriate photolithography and etching processes. A metal(s) of the contacts are deposited in the openings through the dielectric layer 2602. The metal(s) may be deposited using an appropriate deposition process(es), such as CVD, PVD, or the like. Any excess metal(s) may be removed, such as by a CMP and/or by patterning using photolithography and etch processes.

FIG. 26 illustrates a semiconductor device 2600. The illustrated semiconductor device 2600 includes a BJT in the BJT region 104. The BJT includes the collector layer 902, base layer 1102 (e.g., monocrystalline base layer 1102a and polycrystalline base layer 1102c), and emitter layer 1902 (e.g., monocrystalline emitter layer 1902a and polycrystalline emitter layer 1902c). The BJT of the semiconductor device 2600 of FIG. 26 also includes a raised base layer 1402a on the base layer 1102 (e.g., on the polycrystalline base layer 1102c).

The collector layer 902 is over and on the upper surface 120 of the semiconductor substrate 102 and is through an opening in a pedestal dielectric layer 202b, which is also over and on the upper surface of the semiconductor substrate 102. The collector layer 902 is on the n-type doped sub-collector diffusion region 146 in the semiconductor substrate 102. The base layer 1102 (e.g., the monocrystalline base layer 1102a) is over and on the collector layer 902, and the base layer 1102 (e.g., the polycrystalline base layer 1102c) is over and on an upper surface of the pedestal dielectric layer 202b. The pedestal dielectric layer 202b extends laterally from the base layer 1102, such as laterally over and along the upper surface 120 of the semiconductor substrate 102 in a lateral direction from the base layer 1102 towards the n-type collector contact region 2302 and laterally along the isolation structure 122.

The raised base layer 1402a is over and on the base layer 1102 (e.g., the polycrystalline base layer 1102c and, in some instances, a portion of the monocrystalline base layer 1102a). The emitter layer 1902 (e.g., the monocrystalline emitter layer 1902a) is over and on the base layer 1102 (e.g., the monocrystalline base layer 1102a) and is through an opening defined by the emitter dielectric spacers 1702a along sidewalls of the raised base layer 1402a, and the emitter layer 1902 (e.g., the polycrystalline emitter layer 1902c) is over and on the emitter dielectric spacers 1702a and the dielectric protective layer 1502b. Each emitter dielectric spacer 1702a is also along a respective sidewall of the dielectric protective layer 1502b, and the dielectric protective layer 1502b extends over and on the raised base layer 1402a to underlying a corresponding dielectric protective spacer 2102b.

The raised base layer 1402a, as patterned in the semiconductor device 2600, has a substantially uniform thickness as described above. Further, the raised base layer 1402a, as patterned in the semiconductor device 2600, has a substantially continuous upper surface as described above. More specifically, the raised base layer 1402a has a substantially uniform thickness from a lateral distance 2632 away from the emitter layer 1902 (e.g., the polycrystalline emitter layer 1902b) to a corresponding emitter dielectric spacer 1702a. Also, the raised base layer 1402a has a substantially continuous upper surface along the lateral distance 2632 away from the emitter layer 1902 (e.g., the polycrystalline emitter layer 1902b) to a corresponding emitter dielectric spacer 1702a. The dielectric protective layer 1502b is on and over at least a portion of the substantially continuous upper surface of the raised base layer 1402a, and the dielectric protective layer 1502b extends from the emitter dielectric spacer 1702a to a side of the dielectric protective spacer 2102b. At least a portion of the dielectric protective layer 1502b underlies the dielectric protective spacer 2102b.

The metal-semiconductor compound 2502 is on the emitter layer 1902 (e.g., the polycrystalline emitter layer 1902c and/or monocrystalline emitter layer 1902a). The metal-semiconductor compound 2504 is on the raised base layer 1402a. The metal-semiconductor compound 2506 is on the upper surface 120 of the semiconductor substrate 102 on the n-type collector contact region 2302.

In some examples, the BJT may be a heterojunction BJT. As indicated previously, in some examples, the collector layer 902 and the emitter layer 1902 may be silicon, and the base layer 1102 may include silicon germanium. Hence, in some examples, the base layer 1102 may include a semiconductor material dissimilar from respective semiconductor materials of the collector layer 902 and emitter layer 1902. The dissimilar semiconductor materials may form one or more heterojunctions in the BJT, and the BJT may therefore be a heterojunction BJT.

Although not illustrated, the semiconductor device 2600 may include a pFET in the pFET region and an nFET in the nFET region. The pFET region and nFET region are in a CFET region. The pFET includes the gate electrode, gate dielectric layer, embedded stressors, PSD regions, p-type LDDs, and a channel region in the semiconductor substrate 102 underlying the gate electrode. The gate electrode is over and on the gate dielectric layer, and the gate dielectric layer is over and on the upper surface 120 of the semiconductor substrate 102. The p-type LDDs are on laterally opposing sides of the gate electrode and in the semiconductor substrate 102. The channel region is laterally between the p-type LDDs. The embedded stressors and PSD regions are on laterally opposing sides of the gate electrode, with the p-type LDDs and channel region therebetween. Similarly, the nFET includes the gate electrode, gate dielectric layer, NSD regions, n-type LDDs, and a channel region in the semiconductor substrate 102 underlying the gate electrode. The gate electrode is over and on the gate dielectric layer, and the gate dielectric layer is over and on the upper surface 120 of the semiconductor substrate 102. The n-type LDDs are on laterally opposing sides of the gate electrode and in the semiconductor substrate 102. The channel region is laterally between the n-type LDDs. The NSD regions are on laterally opposing sides of the gate electrode, with the n-type LDDs and channel region therebetween. The pFET and nFET may be complementary devices (e.g., complementary metal-oxide-semiconductor (CMOS) devices). In some examples, the pFET may be a p-type metal-oxide-semiconductor (PMOS) transistor, and the nFET may be an n-type metal-oxide-semiconductor (NMOS) transistor.

The semiconductor processing to form the semiconductor device 2600 of FIG. 26 may enable vertical scaling and horizontal scaling. In some examples, for vertical scaling, thicknesses of the collector layer 902, base layer 1102, and emitter layer 1902 may be reduced. In some examples, a thickness of the collector layer 902 does not exceed 200 nm, and a thickness of the base layer 1102 (e.g., the monocrystalline base layer 1102a) does not exceed 100 nm. Further, in some examples, the thickness of the collector layer 902 is in a range from 10 nm to 100 nm, and a thickness of the base layer 1102 (e.g., the monocrystalline base layer 1102a) is in a range from 10 nm to 50 nm. Additionally, in some examples, a thickness of the emitter layer 1902 (e.g., the monocrystalline emitter layer 1902a) does not exceed 100 nm. In some examples, the thickness of the emitter layer 1902 (e.g., the monocrystalline emitter layer 1902a) is in a range from 10 nm to 50 nm. Generally, a thickness of a given layer is in a direction normal to a tangent plane of the underlying surface on which the given layer is formed. However, in some instances, such as with a conformal deposition, a direction normal to a tangent plane of the underlying surface may not be a thickness, such as where a thickness from another tangent plane intersects that direction normal, like at a corner.

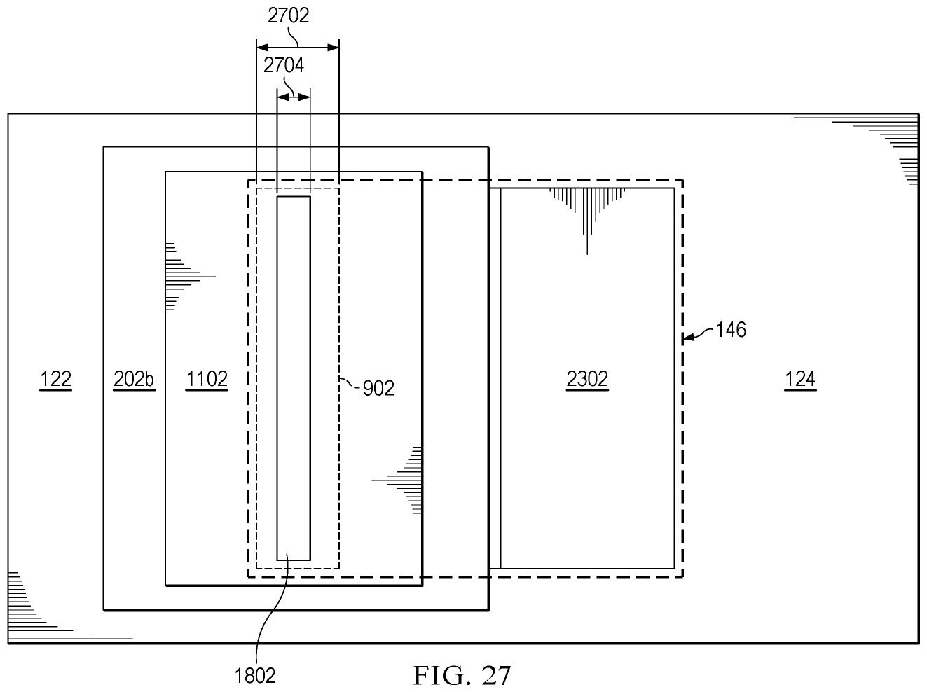

For horizontal scaling, widths of respective openings in which the collector layer 902 and the emitter layer 1902 (e.g., the monocrystalline emitter layer 1902a) are formed, may be reduced. The width of the collector opening 802, in which the collector layer 902 is formed, may be reduced, and the width of the emitter opening 1802, in which the monocrystalline emitter layer 1902a is formed, may be reduced. The semiconductor processing described above may enable horizontal scaling to, e.g., a 28 nm technology node and beyond (e.g., a 21 nm technology node or less). FIG. 27 depicts a layout of components that form the BJT in the semiconductor device 2600 of FIG. 26. Among other things, FIG. 27 shows the lateral boundaries of the pedestal dielectric layer 202b. The collector layer 902 is shown laterally interior within the pedestal dielectric layer 202b, and the layout of the collector layer 902 corresponds to the collector opening 802 shown in FIG. 8. The collector layer 902 (and further, the collector opening 802) has a width 2702. The layout of the base layer 1102 (e.g., the polycrystalline base layer 1102c) is shown relative to the collector layer 902. The emitter opening 1802 shown in FIG. 18 is shown relative to the base layer 1102 and the collector layer 902 and has a width 2704. The emitter layer 1902 (e.g., the monocrystalline emitter layer 1902a) is formed in the emitter opening 1802. One or both of the widths 2702, 2704 may be reduced for horizontal scaling. In some examples, the width 2702 does not exceed 200 nm, and the width 2704 does not exceed 120 nm. Further, in some examples, the width 2702 is in a range from 80 nm to 180 nm, and the width 2704 is in a range from 40 nm to 100 nm.

The BJT in the semiconductor device 2600 of FIG. 26 may have improved characteristics relative to other BJTs. The BJT in the semiconductor device 2600 may have lower base resistance, lower collector resistance, and lower parasitic capacitance (e.g., including base-collector capacitance and collector-substrate capacitance).

Although various examples have been described in detail, it should be understood that various changes, substitutions, and alterations can be made therein without departing from the scope defined by the appended claims.

What is claimed is:

1. A semiconductor device, comprising:
a semiconductor substrate; and
a bipolar junction transistor on the semiconductor substrate, the bipolar junction transistor including:
a collector layer on the semiconductor substrate;
a base layer on the collector layer;
a raised base layer on the base layer;
a first dielectric spacer on the base layer and along a sidewall of the raised base layer; and
an emitter layer on the base layer, the first dielectric spacer being laterally between the raised base layer and the emitter layer, the emitter layer extending over the first dielectric spacer and at least partially over the raised base layer, the raised base layer having a substantially continuous upper surface from a distance away from the emitter layer to the first dielectric spacer underlying the emitter layer.

2. The semiconductor device of claim 1, wherein the raised base layer has a substantially uniform thickness from the distance away from the emitter layer to the first dielectric spacer underlying the emitter layer.

3. The semiconductor device of claim 1, wherein the bipolar junction transistor includes:
a second dielectric spacer along a sidewall surface of the emitter layer; and
a dielectric layer on the substantially continuous upper surface of the raised base layer, the dielectric layer extending from the first dielectric spacer to a side of the second dielectric spacer, wherein a portion of the dielectric layer underlies the second dielectric spacer.

4. The semiconductor device of claim 1, wherein the base layer includes a material dissimilar from a material of the collector layer and a material of the emitter layer.

5. The semiconductor device of claim 4, wherein:
the material of the base layer includes silicon germanium;
the material of the collector layer is silicon; and
the material of the emitter layer is silicon.

6. The semiconductor device of claim 1, further comprising:
a base metal-semiconductor compound on the raised base layer; and
an emitter metal-semiconductor compound on the emitter layer.

7. A method, comprising:
forming a collector layer on a semiconductor substrate;
forming a base layer on and contacting the collector layer;
forming a raised base layer on and contacting the base layer; and
after forming the raised base layer, forming an emitter layer on and contacting the base layer and extending over the raised base layer.

8. The method of claim 7, further comprising forming an inverse mask over the base layer, wherein:
the raised base layer is formed while the inverse mask is over the base layer; and
the emitter layer is formed where the inverse mask was formed.

9. The method of claim 8, further comprising selectively forming a dielectric layer over the raised base layer and not over the inverse mask, the inverse mask being over the base layer when the dielectric layer is selectively formed.

10. The method of claim 8, wherein forming the raised base layer includes selectively epitaxially growing the raised base layer on and contacting the base layer.

11. The method of claim 7, further comprising forming a dielectric layer over the raised base layer, the emitter layer being formed over the dielectric layer.

12. The method of claim 11, wherein the dielectric layer is an oxide layer.

13. The method of claim 12, wherein forming the dielectric layer includes forming the oxide layer by oxidizing the raised base layer at a temperature not exceeding 700° C.

14. A method, comprising:
forming a bipolar junction transistor including:
epitaxially growing a base layer, the base layer being at least partially on a collector layer, the collector layer being on a semiconductor substrate;
forming an inverse mask over the base layer;
epitaxially growing a raised base layer on the base layer while the inverse mask is over the base layer, the inverse mask defining a sidewall of the raised base layer; and
epitaxially growing an emitter layer on the base layer and laterally disposed from the sidewall of the raised base layer, the emitter layer extending over the sidewall of the raised base layer.

15. The method of claim 14, further comprising forming an oxide layer on the raised base layer while the inverse mask is over the base layer.

16. The method of claim 15, wherein forming the oxide layer includes oxidizing the raised base layer at a temperature not exceeding 700° C.

17. The method of claim 15, further comprising forming a first dielectric spacer along the sidewall of the raised base layer and a sidewall of the oxide layer, the sidewall of the raised base layer being aligned with the sidewall of the oxide layer.

18. The method of claim 17, further comprising forming a second dielectric spacer along a sidewall of the emitter layer, the second dielectric spacer being over the oxide layer.

19. The method of claim 14, further comprising forming a dielectric spacer along the sidewall of the raised base layer, the dielectric spacer being laterally between the raised base layer and the emitter layer, the emitter layer extending over the dielectric spacer.

20. The method of claim 19, wherein, after forming the emitter layer, the raised base layer has a substantially uniform thickness from a distance away from the emitter layer to the dielectric spacer underlying the emitter layer.
